(19) United States
(12) Patent Application Publication
(10) Pub. No.: US 2015/0115311 A1
(43) Pub. Date: Apr. 30, 2015

(54) Film-Like Thermosetting Silicone Sealing Material

(71) Applicant: Dow Corning Toray Co., Ltd., Tokyo (JP)

(72) Inventors: Shin Yoshida, Ichihara-shi (JP); Masaaki Amako, Ichihara-shi (JP)

(21) Appl. No.: 14/397,688

(22) PCT Filed: Apr. 23, 2013
(86) PCT No.: PCT/JP2013/062688

§ 371 Date: Oct. 29, 2014

(30) Foreign Application Priority Data
May 1, 2012 (JP) 2012-104531

(51) Int. Cl. C08K 5/5435; H01L 33/56; H01L 21/02

(52) U.S. Cl. CPC C08K 5/5435; H01L 21/02104; H01L 33/56
USPC 257/100; 524/264; 264/272.11

(57) ABSTRACT

The present invention relates to a film-like thermosetting silicone sealing material for sealing a semiconductor element by means of compression molding, the sealing material having an initial torque value of less than 15 dN·m as measured by an MDR (Moving Die Rheometer) at a molding temperature of from room temperature to 200° C., to a method for producing an LED by means of compression molding using the same, and to an LED produced by this method. The sealing material has excellent moldability, causes no problems such as overflow from a die, and has no defects such as voids.

### TECHNICAL FIELD

The present invention relates to a film-like thermosetting silicone sealing material for sealing a semiconductor element such as an LED by means of compression molding, to a method for producing an LED by means of compression molding using the same, and to an LED produced by this method.

Priority is claimed on Japanese Patent Application No. 2012-104531, filed on May 1, 2012, the content of which is incorporated herein by reference.

### BACKGROUND ART

Conventionally, liquid thermosetting sealing materials are known as sealing materials for sealing semiconductor elements such as LEDs. For example, Japanese Unexamined Patent Application Publication No. 2008-227119 describes a production method for a unified structure of an LED chip and a lens formed by subjecting liquid curable silicone composition, curable epoxy resin composition or curable silicone/epoxy resin composition to thermosetting or ultraviolet curing. In addition, Japanese Unexamined Patent Application Publication No. 2006-93354 describes a production method for an optical semiconductor device in which a curable silicone composition is sealed by means of compression molding.

However, when LEDs are sealed using these liquid sealing materials, there are problems in that molding at low temperatures is difficult and that the tact time is long. There have also been problems in that the resin leaks to the outside of the die or in that defects arise due to bubble infiltration at the time of dispensing. These problems arise as a result of molding a liquid and can be solved by molding a solid or semi-solid sealing material.

Japanese Unexamined Patent Application Publication No. 2009-235368 describes a solid or semi-solid addition-curable adhesive silicone composition comprising an organopolysiloxane having a specific structure, an organohydrogenpolysiloxane, a platinum metal-type catalyst, and a fluorescent substance. In addition, Japanese Unexamined Patent Application Publication No. 2002-294202 describes a thermosetting silicone rubber adhesive composition having a Williams plasticity number of from 400 to 800, a green strength (25° C.) of from 0.2 to 0.5 MPa, and visible light transmittance of at least 50% for a cured sheet with a thickness of 1 mm. Although it is described that these silicone compositions are molded into sheet shapes, the thickness of the silicone composition described in Japanese Unexamined Patent Application Publication No. 2009-235368 is thin as from 1 to 500 μm, and the application of the silicone compositions described in Japanese Unexamined Patent Application Publication No. 2002-294202 is limited to the junction of building material glass and building material fittings. Further, since there is no mention of sealing performance, the usefulness of these compositions as sealing materials has been unknown.

Accordingly, conventional sealing materials for sealing semiconductor elements such as LEDs have had problems arising from the moldability and handleability of the sealing materials and the fact that the sealing materials are liquids prone to the development of defects and the like. Moreover, the usefulness of existing sheet-like silicon compositions as sealing materials has been unknown, and it has also been unknown whether such silicone compositions are suitable for applications as sealing materials for LEDs by means of compression molding.

The present invention was conceived in order to solve the problems described above, and an object of the present invention is to provide a film-like thermosetting silicone sealing material for sealing a semiconductor element such as an LED by means of compression molding, the sealing material having excellent moldability, causing no problems such as overflow from a die, and having no defects such as voids.

### DISCLOSURE OF INVENTION

As a result of intensive investigation aimed at achieving the above object, the present inventors arrived at the present invention. That is, the object of the present invention is achieved by a film-like thermosetting silicone sealing material for sealing a semiconductor element by means of compression molding, the sealing material having an initial torque value of less than 15 dN·m as measured by a Moving Die Rheometer (MDR) at a molding temperature of from room temperature to 200° C.

The film-like thermosetting silicone sealing material preferably has a minimum torque value of not more than 10 dN·m within 300 seconds as measured by the MDR.

The film-like thermosetting silicone sealing material preferably has a Williams plasticity number of from 200 to 800 at 25° C. as stipulated in JIS K 6249.

The film-like thermosetting silicone sealing material preferably has a green strength of from 0.01 to 0.6 MPa at 25° C.

Visible light transmittance of the film-like thermosetting silicone sealing material at a thickness of 1 mm is preferably at least 50%.

The film-like thermosetting silicone sealing material of the present invention preferably comprises a film-like silicone composition comprising:
(A) 100 parts by mass of an alkenyl group-containing organopolysiloxane raw rubber;
(B) from 30 to 150 parts by mass of wet hydrophobized reinforcing silica having a BET method specific surface area of at least 200 m²/g, the silica comprising organopolysiloxane units selected from the group consisting of R₃SiO_{1/2} units, R₂SiO_{2/2} units, RSiO_{3/2} units (where each R is independently a monovalent hydrocarbon group), and mixtures thereof and SiO_{4/2} units (the molar ratio of the organopolysiloxane units to the SiO_{4/2} units being from 0.08 to 2.0);
(C) from 0.1 to 10 parts by mass of an organohydrogenpolysiloxane; and
(D) a sufficient amount of a curing agent to cure the composition;
   or is produced by curing the silicone composition to a B-stage.

The film-like thermosetting silicone sealing material may have a film on at least one side.

Moisture permeability of the film is preferably not more than 10 g/m²/24 hr.

In addition, the present invention also relates to a method for producing an LED using the film-like thermosetting silicone sealing material by means of compression molding, the LED having a film on the surface of the sealing material depending on the circumstances.

The present invention also relates to an LED comprising an LED chip, a cured product of a film-like thermosetting silicone sealing material covering the chip, and a film covering the surface of the cured product.

### EFFECTS OF INVENTION

With the present invention, it is possible to provide a film-like thermosetting silicone sealing material for sealing a semiconductor element such as an LED by means of compression molding, the sealing material having excellent moldability, causing no problems such as overflow from a die, and having no defects such as voids.

An LED using the film-like thermosetting silicone sealing material of the present invention has excellent durability as a result of being protected from corrosion by sulfur or the like.

### DETAILED DESCRIPTION OF THE INVENTION

The film-like thermosetting silicone sealing material used in the present invention must have an initial torque value of less than 15 dN·m, preferably not more than 14 dN·m, and more preferably not more than 13 dN·m as measured by a Moving Die Rheometer (MDR) at a molding temperature of from room temperature to 200° C. This is because when the initial torque value is within the range described above, there is no loss of moldability, which makes it possible to reduce damage to the semiconductor element such as an LED and to inhibit the occurrence of deformation or the like of the bonding wire used to electrically connect the semiconductor element. Here, the torque value is a value obtained by measurement with an MDR in accordance with JIS K 6300-2 “Rubber, Unvulcanized—Physical Properties—Section 2: Determination of Vulcanization Properties by an Oscillating Vulcanization Tester”, and the initial torque value is a torque value obtained immediately after the vulcanization.

Although the sealing of a semiconductor element is often performed in a short amount of time such as within 300 seconds, for example, the minimum torque value within 300 seconds as measured by an MDR at the molding temperature described above is preferably not more than 10 dN·m, more preferably not more than 8 dN·m, and most preferably not more than 6 dN·m. The lower limit of the minimum torque value is preferably at least 1 dN·m and more preferably at least 2 dN·m. This is because when the minimum torque value is less than or equal to the upper limit of the range described above, the filling properties are improved in minute portions of the semiconductor element, and when the minimum torque value is greater than or equal to the lower limit of the range described above, problems such as overflow from the die become less likely to occur. Here, the minimum torque value is the minimum torque value during a vulcanization time of 300 seconds beginning immediately after vulcanization in measurements with an MDR in accordance with JIS as described above.

In order to achieve the excellent curability of the film-like thermosetting silicone sealing material, the molding temperature of compression molding must be from room temperature to 200° C. and is preferably from 30° C. to 150° C.

The film-like thermosetting silicone sealing material used in the present invention preferably has a Williams plasticity number of from 200 to 800 at 25° C. as stipulated in JIS K 6249. This is because when the Williams plasticity number is at least 200, the film-like thermosetting silicone sealing material becomes unlikely to overflow from the die, and when the Williams plasticity number is not more than 800, the operability is improved.

The green strength (25° C.), namely uncured strength, of the film-like thermosetting silicone sealing material used in the present invention is preferably from 0.01 to 0.6 MPa. The lower limit of the green strength is more preferably at least 0.1 MPa. The upper limit of the green strength is more preferably not more than 0.5 MPa. This is because when the green strength is greater than or equal to the lower limit of the range described above, it becomes unlikely for problems such as deformation or shredding to occur during handling. When the green strength is less than or equal to the upper limit of the range described above, the handleability is improved, and the loss of plasticity due to the return of plasticization during storage is eliminated, which also improves the processability of the sealing material.

Visible light transmittance of the film-like thermosetting silicone sealing material used in the present invention must be at least 50% for a cured sheet with a thickness of 1 mm, preferably at least 85%, and more preferably at least 90%. This is because when visible light transmittance is not more than 50%, the transparency of the film-like thermosetting silicone sealing material decreases, and the luminescence intensity decreases when the film-like thermosetting silicone sealing material is used for an LED.

The film-like thermosetting silicone sealing material of the present invention preferably comprises a film-like silicone composition comprising:
(A) 100 parts by mass of an alkenyl group-containing organopolysiloxane raw rubber;
(B) from 30 to 150 parts by mass of wet method hydrophobized reinforcing silica having a BET method specific surface area of at least 200 m²/g, the silica comprising organopolysiloxane units selected from the group consisting of R₃SiO_{1/2} units, R₂SiO_{2/2} units, RSiO_{3/2} units (where each R is independently a monovalent hydrocarbon group), and mixtures thereof and SiO_{4/2} units (the molar ratio of the organopolysiloxane units to the SiO_{4/2} units being from 0.08 to 2.0);
(C) from 0.1 to 10 parts by mass of an organohydrogenpolysiloxane; and
(D) a sufficient amount of a curing agent to cure the composition;
   or is produced by curing the silicone composition to the B-stage.

Component (A) is typically called an organopolysiloxane raw rubber, and a substance used as the primary agent of a millable silicone rubber may be used. A representative example of such an organopolysiloxane raw rubber is an alkenyl group-containing organopolysiloxane raw rubber expressed by the average unit formula R′ₐSiO_{(4-a)/2} (where R′ is a monovalent hydrocarbon group or a halogenated alkyl group, examples of monovalent hydrocarbon groups including alkyl groups such as methyl groups, ethyl groups, and propyl groups; alkenyl groups such as vinyl groups and allyl groups; cycloalkyl groups such as cyclohexyl groups; aralkyl groups such as β-phenylethyl groups; and aryl groups such as phenyl groups and tolyl groups; and examples of halogenated alkyl groups including 3,3,3-trifluoropropyl groups and 3-chloropropyl groups; and “a” is from 1.9 to 2.1).

The alkenyl group-containing organopolysiloxane raw rubber of component (A) preferably has at least two silicon-bonded alkenyl groups in one molecule. The molecular structure of component (A) may be either a straight chain or a branched chain structure. Examples of the bond positions of the alkenyl groups in component (A) are molecular chain terminals and/or molecular side chains. The degree of polymerization of this component is ordinarily from 3,000 to 20,000, and the mass-average molecular mass is at least 20×10⁴. The viscosity of this component at 25° C. is at least 10⁶ mPa·s, and the Williams plasticity number at 25° C. is at least 50 and preferably at least 100. The state of the component is a raw rubber state.

Component (A) may be a homopolymer, a copolymer, or a mixture of these polymers. Specific examples of the siloxane unit constituting this component include dimethylsiloxane units, methylvinylsiloxane units, methylphenylsiloxane units, and 3,3,3-trifluoropropylmethylsiloxane units. The molecular chain terminal of component (A) is preferably chain terminated by a triorganosiloxane group or a hydroxyl group, and examples of groups present at the molecular chain terminal include trimethylsiloxy groups, dimethylvinylsiloxy groups, methylvinylhydroxysiloxy groups, and dimethylhydroxysiloxy groups. Examples of such an organopolysiloxane raw rubber include both-terminal dimethylvinylsiloxy group-chain terminated dimethylsiloxane-methylvinylsiloxane copolymer raw rubbers, both-terminal dimethylvinylsiloxy group-chain terminated dimethylpolysiloxane raw rubbers, both-terminal dimethylhydroxysiloxy group-chain terminated dimethylsiloxane-methylvinylsiloxane copolymer raw rubbers, and both-terminal methylvinylhydroxysiloxy group-chain terminated dimethylsiloxane-methylvinylsiloxane copolymer raw rubbers.

The wet method hydrophobized reinforcing silica of component (B) has the function of increasing the mechanical strength in the uncured state and after curing. The wet method hydrophobized reinforcing silica also has the function of providing adhesiveness—adhesive durability, in particular—to an LED chip. Such component (B) is a wet method hydrophobized reinforcing silica having a BET method specific surface area of at least 200 m²/g, the silica comprising organopolysiloxane units selected from the group consisting of R₃SiO_{1/2} units, R₂SiO_{2/2} units, RSiO_{3/2} units (where each R is independently a monovalent hydrocarbon group exemplified by alkyl groups such as methyl groups, ethyl groups, and propyl groups, or aryl groups such as phenyl groups), and mixtures thereof and SiO_{4/2} units (the molar ratio of the organopolysiloxane units to the SiO_{4/2} units being from 0.08 to 2.0).

The amount of the organosiloxane units contained in component (B) is an amount sufficient to hydrophobize the reinforcing silica, and the molar ratio of the organopolysiloxane units to the SiO_{4/2} units is preferably within the range of from 0.08 to 2.0. This is because when the molar ratio is at least 0.08, the adhesive performance with respect to the LED chip is improved, and when the molar ratio is not more than 2.0, the reinforcing performance is remarkably improved. In addition, in order to increase the mechanical strength in the uncured and cured states, the BET method specific surface area must be at least 200 m²/g, preferably at least 300 m²/g, and more preferably at least 400 m²/g.

Component (B) is produced by a method disclosed in Japanese Examined Patent Application Publication No. S61-56255 or U.S. Pat. No. 4,418,165. The amount of component (B) is from 30 to 150 parts by mass and preferably from 50 to 100 parts by mass per 100 parts by mass of component (A).

The organohydrogenpolysiloxane of component (C) is a crosslinking agent of component (A) and is an organopolysiloxane having at least two silicon-bonded hydrogen atoms in one molecule. Examples of the molecular structure of component (C) include a straight chain structure, a partially branched straight chain structure, a branched chain structure, a cyclic structure, and a reticular structure. Examples of the bond positions of the silicon-bonded hydrogen atoms in component (C) are molecular chain terminals and/or molecular side chains. Examples of groups bonding to the silicon atoms other than hydrogen atoms in component (C) are substituted or unsubstituted monovalent hydrocarbon groups including alkyl groups such as methyl groups, ethyl groups, propyl groups, butyl groups, pentyl groups, hexyl groups, and heptyl groups; aryl groups such as phenyl groups, tolyl groups, xylyl groups, and naphthyl groups; aralkyl groups such as benzyl groups and phenetyl groups; and halogenated alkyl groups such as chloromethyl groups, 3-chloropropyl groups, and 3,3,3-trifluoropropyl groups. Examples of such an organohydrogenpolysiloxane include methylhydrogenpolysiloxanes capped at both molecular terminals with trimethylsiloxy groups, dimethylsiloxane-methylhydrogensiloxane copolymers capped at both molecular terminals with trimethylsiloxy groups, methylphenylsiloxane-methylhydrogensiloxane copolymers capped at both molecular terminals with dimethylphenylsiloxy groups, cyclic methylhydrogenpolysiloxanes, and copolymers comprising dimethylhydrogensiloxane units and SiO_{4/2} units.

The amount of component (C) is an amount sufficient to cure the composition. This amount is preferably an amount enabling the silicon-bonded hydrogen atoms to be within the range of from 0.5 to 10 mol and more preferably within the range of from 1 to 3 mol per 1 mol of the silicon-bonded alkenyl groups in the alkenyl group-containing organopolysiloxane raw rubber of component (A). This is because when the number of mols of silicon-bonded hydrogen atoms per 1 mol of silicon-bonded alkenyl groups is greater than or equal to the lower limit of this range in the composition described above, the curing of the composition is sufficient, and when the number of mols is less than or equal to the upper limit of this range, the heat resistance of the cured product of the composition is improved. Specifically, the amount is preferably from 0.1 to 10 parts by mass and more preferably from 0.3 to 5 parts by mass per 100 parts by mass of component (A).

The curing agent of component (D) is a catalyst for curing the composition, examples of which include platinum-based catalysts, organic peroxides, and mixtures of platinum-based catalysts and organic peroxides. Examples of platinum-based catalysts include chloroplatinic acids, alcohol-denatured chloroplatinic acids, chelate compounds of platinum, coordination compounds of chloroplatinic acids and olefins, complexes of chloroplatinic acids and diketones, and complex compounds of chloroplatinic acids and divinyltetramethyldisiloxanes. Examples of organic peroxides include benzoyl peroxide, t-butyl perbenzoate, o-methylbenzoyl peroxide, p-methylbenzoyl peroxide, m-methylbenzoyl peroxide, dicumyl peroxide, and 2,5-dimethyl-2,5-di(t-butyl peroxy)hexane.

The amount of component (D) is an amount sufficient to cure the composition. When a platinum-based catalyst is used, the amount of platinum metal in the platinum-based catalyst is preferably in the range of from 0.1 to 500 ppm and more preferably in the range of from 1 to 100 ppm per 100 parts by mass of component (A). When an organic peroxide is used, the amount of the organic peroxide is preferably from 0.1 to 10 parts by mass per 100 parts by mass of component (A).

An adhesion promoter mainly comprising an organoalkoxysiloxane having organic functional groups such as mercapto groups, amino groups, vinyl groups, allyl groups, hexenyl groups, methacryloxy groups, acryloxy groups, and glycidoxy groups or a partially hydrolyzed condensate thereof may also be compounded as an additional component in order to improve adhesion. Examples of such an adhesion promoter include organoalkoxysilanes such as γ-mercaptopropyltrimethoxysilane, γ-mercaptopropylmethyldimethoxysilane, γ-(2-aminoethyl)aminopropyltrimethoxysilane, γ-methacryloxypropyltrimethoxysilane, γ-acryloxypropyltrimethoxysilane, vinyltri(methoxyethoxy)silane, allyltrimethoxysilane, and γ-glycidoxypropyltrimethoxysilane or partially hydrolyzed condensates thereof; reaction products of these organoalkoxysilanes and triallyl trimellitate or tetraallyl pyromellitate; reactants of alkoxysilanes and siloxane organomers; and mixtures of these alkoxysilanes and reactive organic compounds such as allyl glycidyl ether, glycidyl acrylate, diallyl phthalate, trimethylol propane triacrylate, alkenyl carbonate group-containing compounds, and mercapto acetate group-containing compounds. Of these, γ-methacryloxypropyltrimethoxysilane, γ-glycidoxypropyltrimethoxysilane, mixtures thereof, or reaction mixtures thereof are preferably used. The amount of this adhesion promoter is preferably from 0.1 to 10 parts by mass and more preferably from 0.3 to 5 parts by mass per 100 parts by mass of the organopolysiloxane of component (A).

In addition, various additives known to be added to and compounded with ordinary silicone rubber compositions such as other inorganic fillers, pigments, heat resistant agents, and curing retardants of platinum-based catalysts, for example, may also be added to the film-like thermosetting silicone sealing material used in the present invention as long as the purpose of the present invention is not undermined. Examples of such additives include diatomaceous earth, quartz powder, calcium carbonate, transparent titanium oxide, and transparent red iron oxide. Examples of heat resistant agents include rare earth oxides, cerium silanolate, and cerium fatty acid salts. Examples of curing retardants include acetylene alcohol compounds such as 3-methyl-1-butyl-3-ol, 3,5-dimethyl-1-hexyn-3-ol, and phenylbutynol; enyne compounds such as 3-methyl-3-penten-1-yne and 3,5-dimethyl-3-hexen-1-yne; and other hydrazine compounds, phosphine compounds, mercaptan compounds, benzotriazoles, and methyl tris(methylisobutyloxy)silane.

The film-like thermosetting silicone sealing material of the present invention may be cured to the B-stage. The degree of curing of this film-like thermosetting silicone sealing material is not particularly limited. An example of a possible state is a state in which the film-like thermosetting silicone composition is not completely cured and made to swell with a solvent but not completely dissolved so that the film-like thermosetting silicone composition loses fluidity; that is, a state such as the B-stage defined by JIS K 6800 (curing intermediate of a thermosetting resin).

The film-like thermosetting silicone sealing material of the present invention is obtained by kneading and mixing the components described above with a double roller, a kneader, a Banbury mixer, and the like. Next, examples of methods for processing the obtained composition into a film shape include methods of extruding the composition into a film shape through an extruder provided with a prescribed cap, sandwiching the composition between organic resin films such as polyolefin films or polyester films using a calender roll to form a uniform film shape, or molding the composition into a film shape with a press adjusted to not more than 40° C. In particular, continuously molding the composition by laminating the composition between organic resin films using a calender roll is effective from the perspective of production efficiency. A film-like silicone sealing material molded in this way can be used after being cut from a long roll into a required shape with a cutter or a perforator.

The film-like thermosetting silicone sealing material of the present invention may have a film on at least one side. Examples of films include synthetic resin films such as polyester, polytetrafluoroethylene, polyimide, polyphenylene sulfide, polyamide, polycarbonate, polystyrene, polypropylene, polyethylene, polyvinyl chloride, and polyethylene terephthalate. A polypropylene film is preferable.

In order to achieve excellent moldability in the compression molding of an LED, the thickness of the film-like thermosetting silicone sealing material of the present invention is preferably from 0.1 to 5 mm and more preferably from 0.5 to 1.5 mm.

The film-like thermosetting silicone sealing material of the present invention is used in the compression molding of an LED. An example of a method for producing such an LED is a production method for an LED in which the film-like thermosetting silicone sealing material of the present invention is set in a mold having a cavity at a position opposite the element of a support on which an LED chip is mounted, and the silicone sealing material is then unified by molding the sealing material in a state in which the support is pressed into the mold. It is also possible to perform compression molding in a state in which a film is adhered to one side of the film-like thermosetting silicone sealing material, and in this case, it is possible to produce an LED having the film on the surface of the sealing material.

Moisture permeability of the film adhered to at least one side of the film-like thermosetting silicone sealing material of the present invention is preferably not more than 10 g/m²/24 hr and more preferably not more than 8 g/m²/24 hr. This is because the durability of the LED chip will be diminished if moisture permeability of the film-like thermosetting silicone sealing material is high. In addition, the thickness of the film adhered to at least one side of the film-like thermosetting silicone sealing material of the present invention is at least 10 μm and preferably not more than 100 μm. This is because when the thickness of the film is greater than or equal to the lower limit of the range described above, the risk that the film will be fractured at the time of compression molding is reduced. When the thickness is less than or equal to the upper limit of the range described above, the die compliance of the film is improved, which makes it possible to mold a molded product exactly as prescribed by the design of the die shape.

The present invention also relates to an LED comprising an LED chip mounted on a support, the film-like thermosetting silicone sealing material of the present invention covering the chip, and a film covering the surface of the sealing material. A suitable LED chip is one in which a semiconductor such as InN, AlN, GaN, ZnSe, SiC, GaP, GaAs, GaAlAs, GaAlN, AlInGaP, InGaN, or AlInGaN is formed as a light-emitting layer on a substrate by liquid phase epitaxy or MOCVD. Examples of supports include organic resin substrates such as ceramic substrates, silicon substrates, metal substrates, polyimide resins, epoxy resins, and BT resins. In addition to providing a mount for the LED chip, the support may also have an electrical circuit, a bonding wire such as a gold wire or aluminum wire for electrically connecting the circuit and the LED chip, external leads for the circuit, and the like. When a plurality of chips is mounted, the chips can be established as separate optical devices by cutting or fracturing the support.

The film-like thermosetting silicone sealing material of the present invention is formed integrally when the LED chip is sealed and is preferably adhered to the support and the LED chip. The shape of the silicone cured product is not particularly limited, and examples include a convex lens shape, a truncated cone shape, a Fresnel lens shape, a concave lens shape, and a truncated quadrangular pyramid. The shape is preferably a convex lens shape.

### EXAMPLES

Hereinafter, the present invention will be described in detail using examples. In the examples, the content of the components referred to as “parts” means “parts by mass”. Note that the present invention is not limited to these examples.

### Reference Example 1

### Synthesis of Wet Method Hydrophobized Reinforcing Silica

First, 277 g of octamethylcyclotetrasiloxane, 4.6 g of 1,3,5,7-tetramethyl-1,3,5,7-tetravinylcyclotetrasiloxane, 517 g of methyltrimethoxysilane, and 0.43 g of potassium hydroxide serving as a catalyst were reacted for approximately 2 hours at a temperature of 105° C. to produce a hydrophobizing agent comprising a ring-opened and rearranged organopolysiloxane. The potassium hydroxide was neutralized with carbonic acid gas. When the obtained organopolysiloxane was analyzed, it was observed that the substance is a straight-chain organopolysiloxane comprising 0.7 mol % methylvinylsiloxane groups.

Next, wet method hydrophobized reinforcing silica was synthesized as described below using a hydrophobizing agent comprising the organopolysiloxane obtained above. That is, 118 g of methanol, 32 g of concentrated ammonia water, and 39 g of the hydrophobizing agent obtained above were loaded into a glass reaction container and mixed uniformly with an electromagnetic mixer. Next, 96 g of methyl orthosilicate was added at once to the mixture while the mixture was stirred vigorously. The reaction product became gelatinous after 15 seconds, and stirring was discontinued. The product was left to stand and age in this state while hermetically sealed at room temperature to obtain a dispersion liquid of wet method hydrophobized reinforcing silica. Methanol and ammonia gas were removed from this silica dispersion liquid to produce wet method hydrophobized reinforcing silica comprising (CH₃)₂SiO_{2/2} units, (CH₃)(CH═CH₂)SiO_{2/2} units, CH₃SiO_{3/2} units, and SiO_{4/2} units, the molar ratio of the total of the (CH₃)₂SiO_{2/2} units, the (CH₃)(CH═CH₂)SiO_{2/2} units, and the CH₃SiO_{3/2} units to the SiO_{4/2} units being 1.0. The BET method specific surface area of this wet method hydrophobized reinforcing silica was 540 m²/g.

### Practical Example 1

### Preparation of a Film-Like Thermosetting Silicone Sealing Material

First, 100 parts of a dimethylsiloxane-methylvinylsiloxane copolymer raw rubber comprising 99.63 mol % of dimethylsiloxane units and 0.37 mol % of methylvinylsiloxane units and having both terminals of the molecular chains chain terminated with dimethylvinylsiloxy groups (degree of polymerization: 4,000) and 75 parts of the wet method hydrophobized reinforcing silica produced above with a BET method specific surface area of 540 m²/g were loaded into a kneader mixer and kneaded for 60 minutes at 180° C. After being cooled, 3.0 parts of a methylhydrogenpolysiloxane having molecular terminals chain terminated with trimethylsiloxy groups (silicon-bonded hydrogen atom content: 1.5%) with a viscosity of 7 mPa·s at 25° C. and a complex of a chloroplatinic acid and 1,3-divinyltetramethyldisiloxane were mixed into the obtained silicone rubber base so that the amount of platinum metal was 10 ppm, and a transparent thermosetting silicone rubber adhesive composition was obtained. A film-like thermosetting silicone sealing material (I) with a thickness of 1 mm was prepared by passing this composition through a calender roll. The properties of this film-like thermosetting silicone sealing material (I) are shown in Table 1.

### Practical Example 2

A film-like thermosetting silicone sealing material (II) cured to the B-stage was prepared by heating the film-like thermosetting silicone sealing material (I) prepared in Practical Example 1 for 5 minutes at 120° C. The properties of this film-like thermosetting silicone sealing material (II) are shown in Table 1.

### Practical Example 3

A film-like thermosetting silicone sealing material (III) cured to the B-stage was prepared by heating the film-like thermosetting silicone sealing material (I) prepared in Practical Example 1 for 7 minutes at 120° C. The properties of this film-like thermosetting silicone sealing material (III) are shown in Table 1.

### Practical Example 4

A film-like thermosetting silicone sealing material (IV) was prepared in the same manner as in Practical Example 1 with the exception that the 75 parts of wet method hydrophobized reinforcing silica used in Practical Example 1 was replaced with 40 parts of wet method hydrophobized reinforcing silica. The properties of this film-like thermosetting silicone sealing material (IV) are shown in Table 1.

### Practical Example 5

A film-like thermosetting silicone sealing material (V) was prepared in the same manner as in Practical Example 1 with the exception that 15 parts of a quartz powder with an average particle diameter of 5 μm was further added as a semi-reinforcing filler in Practical Example 1. The properties of this film-like thermosetting silicone sealing material (V) are shown in Table 1.

### Practical Example 6

### Compression Molding Test

An upper die and a lower die attached to a compression molding apparatus were heated to 150° C. A die out of which a dome shape was carved was used as the lower die. A substrate on which an LED chip was mounted was set in the upper die so that the LED chip faced downward. Protective films and base films attached to both sides of the film-like thermosetting silicone sealing material (I) were peeled away. A mold releasing film (AFLEX 50LM) made of a tetrafluoroethylene resin (ETFE) was set on the lower die, and the mold releasing film was adsorbed by air suction. The film-like thermosetting silicone sealing material (I) was disposed on the mold releasing film, and the upper and lower dies were aligned without vacuuming. Compression molding was then performed for 5 minutes while applying a load of 3 MPa at 150° C. in a state in which the substrate was sandwiched between the upper and lower dies. Then, the resin-sealed substrate was removed from the die and heat treated for one hour in a 150° C. oven. A dome-shaped silicone coating was obtained. The appearance of the obtained silicone-sealed LED was observed to monitor the presence or absence of overflow, voids, and wire deformation. In addition, a current was applied to the obtained silicone-sealed LED, and the presence or absence of decreases in luminescence brightness was monitored visually.

### Practical Examples 7 to 14

Compression molding tests were performed in the same manner as in Practical Example 6 with the exception that the vacuuming was performed for 10 seconds. The other molding conditions are shown in Table 2.

### Reference Example 2

### Preparation of a Liquid Silicone Sealing Material

A liquid silicone sealing material with a viscosity of 2,900 mPa·s was prepared by uniformly mixing 60 parts of a branched chain organopolysiloxane (vinyl group content=5.6 mass %, phenyl group content ratio out of all silicon-bonded organic groups=50 mol %) represented by the average unit formula:

(PhSiO_{3/2})_{0.75}(ViMe₂SiO_{1/2})_{0.25}

(where Ph represents a phenyl group and Vi represents a vinyl group),
15 parts of a methylphenylpolysiloxane capped at both molecular terminals with dimethylvinylsiloxy groups (vinyl group content=1.5 mass %, phenyl group content ratio out of all of the silicon atom-bonded organic groups=49 mol %), 23 parts of a straight organopolysiloxane (silicon-bonded hydrogen atom content=0.60 mass %, phenyl group content ratio out of all of the silicon atom-bonded organic groups=33 mol %) represented by the formula:

HMe₂SiO(Ph₂SiO)SiMe₂H

(where Me represents a methyl group),
2 parts of a straight organopolysiloxane (silicon-bonded hydrogen atom content=0.65 mass %, phenyl group content ratio out of all of the silicon atom-bonded organic groups=25 mol %, number-average molecular weight=2,260) represented by the average unit formula:

(PhSiO_{3/2})_{0.60}(HMe₂SiO_{1/2})_{0.40}

a 1,3-divinyl-1,1,3,3-tetramethyldisiloxane complex of platinum (in this composition, the amount of platinum metal in the complex is 2.5 ppm in terms of mass units), and 0.05 parts of 2-phenyl-3-butyn-2-ol.

### Comparative Example 1

A glass epoxy substrate was disposed on the upper die of a compression molding apparatus. Next, a mold releasing film made of a tetrafluoroethylene resin disposed on the lower die was hermetically attached to the lower die by air suction. After 1.4 mL of a prepared sample was applied to the mold releasing film, the upper and lower dies were aligned. Compression molding was then performed for 5 minutes while applying a load of 3 MPa at 120° C. without vacuuming in a state in which the substrate was sandwiched between the upper and lower dies. Then, the resin-sealed substrate was removed from the die and heat treated for one hour in a 150° C. oven.

### Comparative Examples 2 to 4

Molding tests were performed in the same manner as in Comparative Example 1 with the exception that vacuuming was performed for 10 seconds. The other molding conditions are shown in Table 2.

### [MDR Measurement Conditions]

The temperature of a measurement device (Rheometry, MDR 2000P, manufactured by Alpha Technologies) was set to the measurement temperature. In order to prevent the test piece from making contact with the dies, thin films (Lumirror produced by Toray Industries, Inc., 25 μm) were made to sandwich the test piece from above and below. A 6 g test piece was set in a disc-shaped hollow part of the die constituted by a fixed lower die and an elevating/lowering upper die. The upper and lower dies were hermetically sealed, and the torque value immediately after being hermetically sealed (curing time of 0 seconds) was recorded as the initial torque value under conditions with a frequency of 1.66 Hz and an oscillating angle of 1°. The results are shown in Table 2.

Further, the minimum value of the torque up to a molding time of 300 seconds was recorded as the minimum torque. The results are shown in Table 2.

TABLE 1

| | Williams | Green | Visible light |
|---|---|---|---|
| | plasticity number | strength | transmittance |
| | (mm × 100) | (MPa) | (%) |
| Film-like silicone sealing | 650 | 0.33 | 92 |
| material (I) | | | |
| Film-like silicone sealing | 690 | 0.49 | 92 |
| material (II) | | | |
| Film-like silicone sealing | 750 | 0.58 | 92 |
| material (III) | | | |
| Film-like silicone sealing | 290 | 0.12 | 82 |
| material (IV) | | | |
| Film-like silicone sealing | 660 | 0.34 | 35 |
| material (V) | | | |

TABLE 2

| | | Molding conditions | | | | | | | | | |
|---|---|---|---|---|---|---|---|---|---|---|---|
| | | | Initial | | | | | | | | |
| | | | torque value | | | | | | | | |
| | | | at the | Minimum | | | Results | | | | |
| | | Molding | molding | torque | Vacuuming | Molding | | | | Wire | LED |
| | | temperature | temperature | value | time | time | | | Dome | defor- | luminescence |
| Sample | | (° C.) | (dN · m) | (dN · m) | (seconds) | (seconds) | Overflow | Voids | shape | mation | intensity |
| Practical | Film-like | 150 | 7 | 3.4 | 0 | 300 | ∘ | ∘ | ∘ | ∘ | ∘ |
| Example 6 | silicone | | | | | | | | | | |
| | sealing | | | | | | | | | | |
| | material (I) | | | | | | | | | | |
| Practical | Film-like | 150 | 7 | 3.4 | 10 | 300 | ∘ | ∘ | ∘ | ∘ | ∘ |
| Example 7 | silicone | | | | | | | | | | |
| | sealing | | | | | | | | | | |
| | material (I) | | | | | | | | | | |
| Practical | Film-like | 150 | 7 | 3.4 | 10 | 10 | ∘ | ∘ | ∘ | ∘ | ∘ |
| Example 8 | silicone | | | | | | | | | | |
| | sealing | | | | | | | | | | |
| | material (I) | | | | | | | | | | |
| Practical | Film-like | 30 | 7 | 5.5 | 10 | 10 | ∘ | ∘ | ∘ | ∘ | ∘ |
| Example 9 | silicone | | | | | | | | | | |
| | sealing | | | | | | | | | | |
| | material (I) | | | | | | | | | | |
| Practical | Film-like | 100 | 7 | 3.2 | 10 | 300 | ∘ | ∘ | ∘ | ∘ | ∘ |
| Example 10 | silicone | | | | | | | | | | |
| | sealing | | | | | | | | | | |
| | material (I) | | | | | | | | | | |
| Practical | Film-like | 100 | 9 | 4.0 | 10 | 300 | ∘ | ∘ | ∘ | ∘ | ∘ |
| Example 11 | silicone | | | | | | | | | | |
| | sealing | | | | | | | | | | |
| | material (II) | | | | | | | | | | |
| Practical | Film-like | 100 | 12 | 6.1 | 10 | 300 | ∘ | ∘ | ∘ | Δ | Δ |
| Example 12 | silicone | | | | | | | | | | |
| | sealing | | | | | | | | | | |
| | material (III) | | | | | | | | | | |
| Practical | Film-like | 100 | 5 | 2.2 | 10 | 300 | ∘ | ∘ | ∘ | ∘ | ∘ |
| Example 13 | silicone | | | | | | | | | | |
| | sealing | | | | | | | | | | |
| | material (IV) | | | | | | | | | | |
| Practical | Film-like | 100 | 7 | 3.5 | 10 | 300 | ∘ | ∘ | ∘ | ∘ | Δ |
| Example 14 | silicone | | | | | | | | | | |
| | sealing | | | | | | | | | | |
| | material (V) | | | | | | | | | | |
| Comparative | Liquid | 150 | 0 | 0.0 | 0 | 300 | ∘ | x | ∘ | ∘ | ∘ |
| Example 1 | silicone | | | | | | | | | | |
| | sealing | | | | | | | | | | |
| | material | | | | | | | | | | |
| Comparative | Liquid | 150 | 0 | 0.0 | 10 | 300 | x | ∘ | ∘ | ∘ | ∘ |
| Example 2 | silicone | | | | | | | | | | |
| | sealing | | | | | | | | | | |
| | material | | | | | | | | | | |
| Comparative | Liquid | 30 | 0 | 0.0 | 10 | 300 | x | ∘ | x | — | — |
| Example 3 | silicone | | | | | | | | | | |
| | sealing | | | | | | | | | | |
| | material | | | | | | | | | | |
| Comparative | Liquid | 150 | 0 | 0.0 | 10 | 10 | x | ∘ | x | — | — |
| Example 4 | silicone | | | | | | | | | | |
| | sealing | | | | | | | | | | |
| | material | | | | | | | | | | |

As shown in Table 1, there was no overflow or liquid discharge process in Practical Examples 6 to 14 using a film-like silicone sealing material, so no voids were generated. It was also possible to obtain a good dome shape even when the temperature was varied. On the other hand, in Comparative Examples 1 to 4 using a liquid silicone sealing material, voids were generated when vacuuming of the liquid was not performed. In addition, overflow occurred when vacuuming was performed. Further, when the curing time was short or the temperature was too low, the liquid silicone sealing material did not cure sufficiently, so a good dome shape was not obtained.

When molding was performed using the film-like silicone sealing material (HI), an LED chip with weak luminescence intensity was generated. This may have been due to deformation in the wire bonding of the LED. In Practical Example 14 using the silicone sealing material (V) with low visible light transmittance, the luminescence intensity of the LED was weak.

### Practical Example 15

### LED Having a Film on the Surface of the Sealing Material

An upper die and a lower die attached to a compression molding apparatus were heated to 100° C. A die out of which a dome shape was carved was used as the lower die. A substrate on which an LED chip was mounted was set in the upper die so that the LED chip faced downward. A protective plastic film (2500H Torayfan produced by Toray Industries, Inc., 60 μM thick) attached to one side of the film-like thermosetting silicone sealing material (I) was peeled away. The surface from which the film was peeled was made to face the device side, and the side with the remaining plastic film (2500H Torayfan produced by Toray Industries, Inc., 60 μm thick) was disposed on the die. The upper and lower dies were aligned, and compression molding was performed for 5 minutes while applying a load of 3 MPa at 100° C. in a state in which the substrate was sandwiched between the upper and lower dies. Then, the resin-sealed substrate was removed from the die and heat treated for one hour in a 150° C. oven. An LED with a plastic film attached to the top of the silicone sealing material was obtained. When the appearance of the obtained LED was observed to monitor the presence or absence of overflow, voids, wire deformation, and decreases in luminescence brightness, the LED was satisfactory in all respects. This LED was left to stand for 4 hours in a sulfur atmosphere at 80° C., and when the LED was monitored for discoloration of the silver electrodes thereof due to sulfur corrosion, no discoloration was observed.

In contrast, an LED was obtained in the same manner as described above with the exception that the plastic films attached to both sides of the film-like thermosetting silicone sealing material (I) were peeled away. When the appearance of the obtained LED was observed to monitor the presence or absence of overflow, voids, wire deformation, and decreases in luminescence brightness, the LED was satisfactory in all respects. The LED was left to stand for 4 hours in a sulfur atmosphere at 80° C., and when the LED was monitored for discoloration of the silver electrodes thereof due to sulfur corrosion, the silver electrodes had turned a dark reddish-brown color.

When the moisture permeabilities of the film-like silicone sealing material with a thickness of 1 mm after being cured for 1 hour at 150° C. and the plastic film layer were respectively measured, the following values were obtained. It was ascertained that an LED device with good anti-sulfur corrosion properties can be obtained by attaching a plastic film having moisture permeability of not more than 10 g/m²/24 hr to the top of the sealing material.

### [Moisture Permeability]

Plastic film layer of the practical examples (60 μm thick): 7 g/m²/24 hr.

Film-like silicone sealing material (film-like silicone sealing material (I)): 93 g/m²/24 hr.

Plastic film layer and sealing material of the practical examples: 4 g/m²/24 hr.

1. A film-like thermosetting silicone sealing material for sealing a semiconductor element by compression molding, wherein the sealing material has an initial torque value of less than 15 dN·m as measured by a Moving Die Rheometer (MDR) at a molding temperature of from room temperature to 200° C.

2. The film-like thermosetting silicone sealing material according to claim 1, wherein a minimum torque value within 300 seconds as measured by the MDR is not more than 10 dN·m.

3. The film-like thermosetting silicone sealing material according to claim 1, wherein the sealing material has a Williams plasticity number at 25° C. as stipulated in JIS K 6249 of from 200 to 800.

4. The film-like thermosetting silicone sealing material according to claim 1, wherein the sealing material has a green strength at 25° C. of from 0.01 to 0.6 MPa.

5. The film-like thermosetting silicone sealing material according to claim 1, wherein the sealing material has visible light transmittance at a thickness of 1 mm of at least 50%.

6. The film-like thermosetting silicone sealing material according to claim 1, wherein the sealing material comprises a film-like silicone composition comprising:
(A) 100 parts by mass of an alkenyl group-containing organopolysiloxane raw rubber;
(B) from 30 to 150 parts by mass of wet method hydrophobized reinforcing silica having a BET method specific surface area of at least 200 m²/g, wherein the silica comprises organopolysiloxane units selected from the group consisting of R₃SiO_{1/2} units, R₂SiO_{2/2} units, RSiO_{3/2} units, where each R is independently a monovalent hydrocarbon group, and mixtures thereof and SiO_{4/2} units, wherein the molar ratio of the organopolysiloxane units to the SiO_{4/2} units is from 0.08 to 2.0[N];
(C) from 0.1 to 10 parts by mass of an organohydrogenpolysiloxane; and
(D) a sufficient amount of a curing agent to cure the composition.

7. The film-like thermosetting silicone sealing material according to claim 1, wherein the sealing material has a film on at least one side.

8. The film-like thermosetting silicone sealing material according to claim 7, wherein moisture permeability of the film is not more than 10 g/m²/24 hr.

9. A method for producing an LED by compression molding using the film-like thermosetting silicone sealing material according to claim 1.

10. A method for producing an LED by compression molding, wherein the LED has a film on a surface of a sealing material, the LED comprising the film-like thermosetting silicone sealing material having a film on at least one side according to claim 7.

11. The method according to claim 10, wherein moisture permeability of the film is not more than 10 g/m²/24 hr.

12. An LED comprising an LED chip, a cured product of a film-like thermosetting silicone sealing material covering the chip, and a film covering a surface of the cured product.

13. The LED according to claim 12, wherein moisture permeability of the film is not more than 10 g/m²/24 hr.

14. The film-like thermosetting silicone sealing material according to claim 1, wherein the sealing material comprises a film-like silicone composition and wherein the sealing material is produced by curing the silicone composition to a B-stage.
